(19) United States
(12) Patent Application Publication
(10) Pub. No.: US 2025/0237692 A1
(43) Pub. Date: Jul. 24, 2025

(54) DIAGNOSIS DEVICE

(71) Applicant: TOYOTA JIDOSHA KABUSHIKI KAISHA, Toyota-shi (JP)

(72) Inventor: Minoru HIDA, Nisshin-shi (JP)

(73) Assignee: TOYOTA JIDOSHA KABUSHIKI KAISHA, Toyota-shi (JP)

(21) Appl. No.: 19/008,805

(22) Filed: Jan. 3, 2025

(30) Foreign Application Priority Data
Jan. 18, 2024 (JP) 2024-006225

(51) Int. Cl. G01R 31/28

(52) U.S. Cl. CPC G01R 31/2837

(57) ABSTRACT

A diagnosis device for detecting an abnormality of an ideal diode in an electric circuit including a DC-DC converter, a battery, and an ideal diode in which an output of a DC-DC converter is connected to an anode side and a battery is connected to a cathode side, the diagnosis device comprising: an acquisition unit that acquires an output voltage of a DC-DC converter in a state where an operation is stopped with respect to an ideal diode using an output of DC-DC converter as a power source; and a determination unit that determines that the ideal diode is abnormal when the output voltage is equal to or higher than a predetermined threshold.

### CROSS-REFERENCE TO RELATED APPLICATION

This application claims priority to Japanese Patent Application No. 2024-006225 filed on Jan. 18, 2024, incorporated herein by reference in its entirety.

### BACKGROUND

### 1. Technical Field

The present disclosure relates to a diagnosis device that makes a diagnosis about control of an ideal diode.

### 2. Description of Related Art

Japanese Unexamined Patent Application Publication No. 2022-174245 (JP 2022-174245 A) discloses an in-vehicle electric circuit that uses an ideal diode that realizes ideal diode characteristics in which a forward voltage is zero and a current flows in only one direction.

This ideal diode is realized by a circuit including at least a metal-oxide-semiconductor field-effect transistor (hereinafter referred to as a “MOSFET”) that operates in synchronous rectification, and a gate control function that switches the MOSFET between a conduction state (ON operation) and a cutoff state (OFF operation), for example. In general, an ideal diode integrated circuit (IC) in which the MOSFET and the gate control function are integrated, a configuration in which a discrete MOSFET is controlled using an ideal diode controller IC in which only the gate control function is integrated, and the like are known as the ideal diode.

### SUMMARY

When the MOSFET remains conductive due to an abnormality caused in the gate control function, or so-called ON fixation occurs, an unintended reverse current flow occurs in the ideal diode. This reverse current flow has a considerable effect on a circuit that uses the ideal diode, and therefore it is necessary to appropriately detect the ON fixation of the ideal diode.

The present disclosure has been made in view of the above issue, and an object of the present disclosure is to provide a diagnosis device capable of appropriately detecting ON fixation of an ideal diode.

In order to address the above issue, an aspect of the present disclosure provides a diagnosis device
that detects an abnormality of an ideal diode in an electric circuit including a direct-current (DC)-DC converter, a battery, and the ideal diode, to an anode side of which an output of the DC-DC converter is connected and to a cathode side of which the battery is connected, the diagnosis device including:
an acquisition unit that acquires an output voltage of the DC-DC converter with operation of the DC-DC converter stopped, the ideal diode being powered by the output of the DC-DC converter; and
a determination unit that determines that the ideal diode is abnormal when the output voltage is equal to or more than a predetermined threshold value.

With the diagnosis device according to the present disclosure, when the power source of the ideal diode is taken from the output of the DC-DC converter, the voltage of the battery appears on the output side, even if the operation of the DC-DC converter is stopped, as long as ON fixation of the ideal diode is caused. Therefore, it is possible to appropriately detect ON fixation of the ideal diode based on the output voltage of the DC-DC converter.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of an electric circuit including a diagnosis device and an ideal diode according to an embodiment of the present disclosure;

FIG. 2 is a process flow chart of the diagnostic control of the ideal diode executed by the diagnosis device at the time of IG-OFF;

FIG. 3 is a process flow chart of the diagnostic control of the ideal diode executed by the diagnosis device at the time of IG-ON; and

FIG. 4 is a diagram showing another configuration of an ideal diode.

### DETAILED DESCRIPTION OF EMBODIMENTS

The diagnosis device according to the present disclosure detects the generation of ON fixing of the ideal diode based on whether the voltage of the battery appears at the output terminal of DC-DC converter via the ideal diode when the operation of DC-DC converter is stopped by utilizing the electric conduction between the anode side and the cathode side when the ideal diode is ON fixed. Hereinafter, an embodiment of the present disclosure will be described in detail with reference to the drawings.

### Embodiment

### Configuration

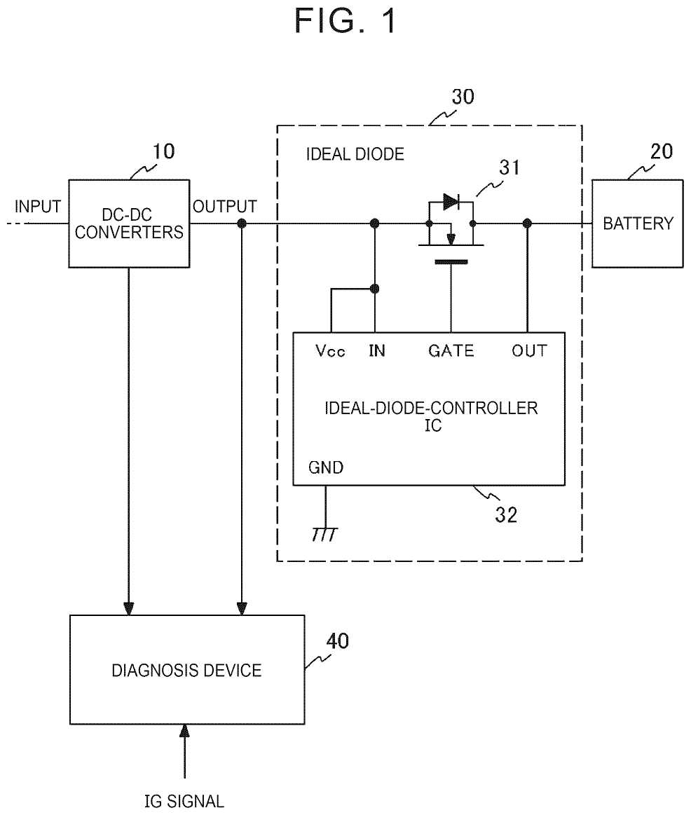

FIG. 1 is a block diagram illustrating a schematic configuration of an electric circuit including a diagnosis device 40 and an ideal diode 30 according to an embodiment of the present disclosure. The diagram illustrated in FIG. 1 includes a DC-DC converter 10, a battery 20, an ideal diode 30, and a diagnosis device 40. DC-DC converters 10, the batteries 20, the ideal diode 30, and the diagnosis device 40 can be mounted on vehicles or the like.

DC-DC converter 10 is a power converter capable of converting power of a first voltage inputted from a power source (not shown) such as a generator or a battery into power of a predetermined second voltage and outputting the converted power. DC-DC converters 10 include configurations such as a step-up/step-down circuit including switching elements, coils, and the like, and a driver circuit for controlling a step-up/step-down operation including a microcomputer and the like.

The battery 20 is a secondary battery configured to be chargeable and dischargeable, such as a lithium-ion battery. The battery 20 is connected to DC-DC converter 10 via an ideal diode 30 so that it can be charged by the electric power outputted from DC-DC converter 10. Further, the battery 20 can supply the stored electric power to a predetermined device (not shown).

The ideal diode 30 is a diode that realizes an ideal diode characteristic in which the forward voltage is zero and current flows only in one direction. This ideal diode 30 can significantly reduce the power loss compared to a discrete rectifier diode. The ideal diode 30 illustrated in FIG. 1 includes a discrete MOSFET 31 and an ideal diode controller IC 32.

The ideal diode 30 is inserted between DC-DC converter 10 and the battery 20 with the output of DC-DC converter 10 connected to the anode side and the battery 20 connected to the cathode side. More specifically, the source of MOSFET 31 (anode side of the body diode) is connected to the output of DC-DC converter 10, and the drain of MOSFET 31 (cathode side of the body diode) is connected to the battery 20.

The ideal diode controller IC 32 is a driver for controlling the gate-voltage (GATE) of MOSFET 31 to control the conduction/disconnection between the source-drain of MOSFET 31. The ideal diode controller IC 32 is provided with a backflow preventing function for controlling MOSFET 31 to be shut off when a current flowing backward from the battery 20 (OUT) side to DC-DC converter 10 (IN) side is detected. The power supply (Vcc) of the ideal diode controller IC 32 is connected to the output of DC-DC converter 10, and the ideal diode controller IC 32 can operate if there is an output (power supplied) of a voltage from DC-DC converter 10. When the ideal-diode-controller IC 32 without power is stopped (shutdown), MOSFET 31 is controlled to be shut off (normally-off).

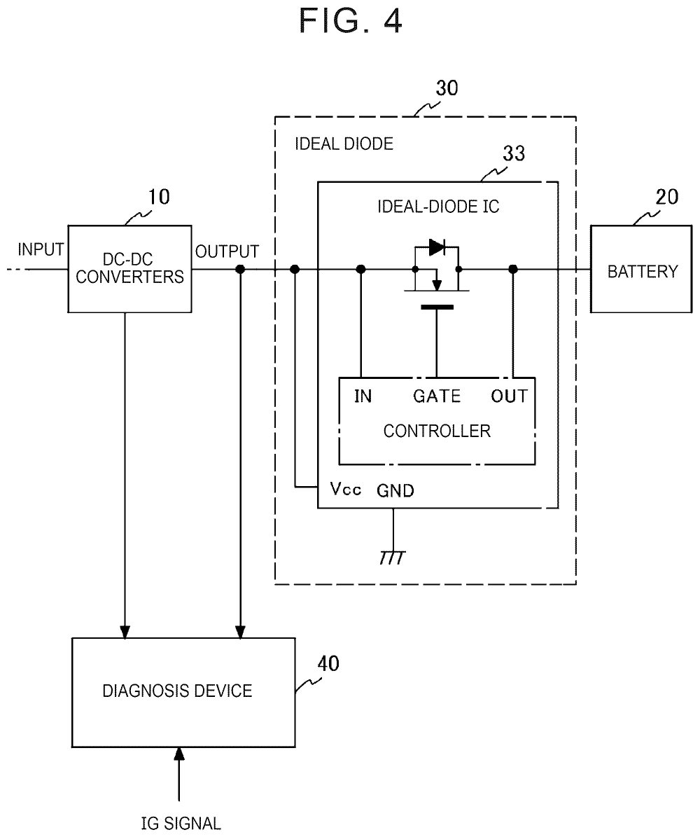

The ideal diode 30 may be configured by the discrete MOSFET 31 and the ideal diode controller IC 32 shown in FIG. 1. The ideal diode 30 may be an ideal diode IC 33 in which MOSFET and controllers as shown in FIG. 4 are integrated in one chip.

The diagnosis device 40 is configured to perform diagnosis on the control of the ideal diode 30. The diagnosis device 40 acquires (receives) at least information on the operation status (operation, stoppage) of DC-DC converter 10 and information on the voltage (hereinafter referred to as “output voltage”) appearing at the output of DC-DC converter 10. When DC-DC converter 10, the battery 20, the ideal diode 30, and the diagnosis device 40 are mounted on the vehicle, the diagnosis device 40 further acquires (inputs) an IG signal which is information indicating a condition (IG-ON, IG-OFF) of the ignition of the vehicle. Then, the diagnosis device 40 performs diagnosis related to the determination of the presence or absence of an abnormality in the control of the ideal diode 30 based on the plurality of acquired information. The diagnostic control executed by the diagnosis device 40 will be described in detail below.

### Control

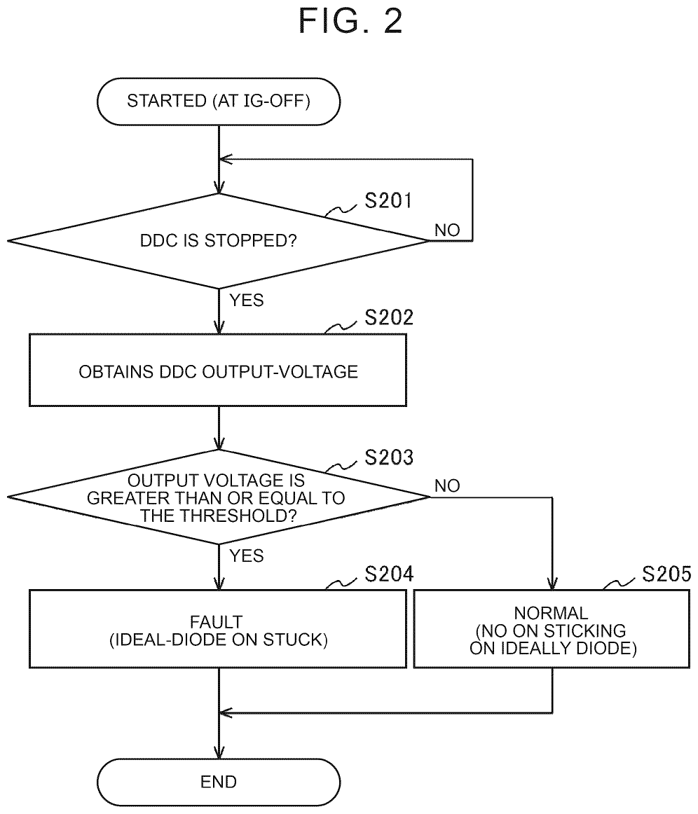

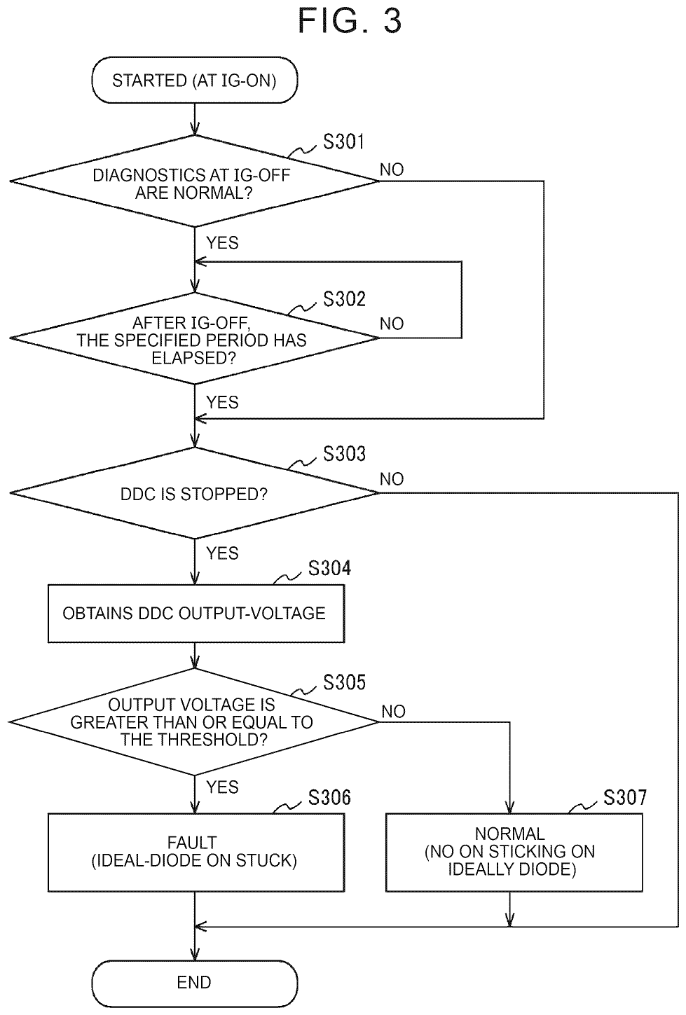

Next, with further reference to FIG. 2 and FIG. 3, control performed by the diagnosis device 40 according to an embodiment of the present disclosure will be described.

FIG. 2 is a flow chart for explaining a process sequence of diagnostic control of the ideal-diode 30 executed by the diagnosis device 40 at the time of IG-OFF. The diagnostic control of the ideal diode 30 illustrated in FIG. 2 is started when the ignition of the vehicle is turned to the off-state (IG-OFF). The ignition condition of the vehicle can be 10 determined by means of an IG signal.

### S201

The diagnosis device 40 determines whether or not DC-DC converters 10 (DDC) are stopped. This determination can be made by information about the operating conditions of DC-DC converters 10 or by IG signaling indicating the in-ignition condition of the vehicles. When the diagnosis device 40 determines that DC-DC converters 10 are stopped (S201, Yes), the process proceeds to S202.

### S202

The diagnosis device 40 acquires the output-voltage of DC-DC converter 10 (DDC). The output voltage can be obtained by monitoring the output terminal of DC-DC converter 10 using, for example, a voltage sensor. When the diagnosis device 40 acquires DC-DC converters 10 (DDC), the process proceeds to S203.

### S203

The diagnosis device 40 determines whether or not the output-voltage of DC-DC converters 10 is greater than or equal to a predetermined threshold. This determination is made in order to confirm that the anode side and the cathode side of the ideal diode 30 are conductive and that the power supply voltage necessary for the operation is supplied to the ideal diode 30. Therefore, the threshold is set to a predetermined value (however, a value smaller than the voltage of the battery 20) that is larger than the voltage that appears as the output-side voltage of DC-DC converter 10 when the ideal diode 30 is in the shut-off state.

When the diagnosis device 40 determines that the output voltage of DC-DC converters 10 is equal to or higher than the threshold (S203, Yes), the process proceeds to S204. On the other hand, if the diagnosis device 40 determines that the output voltage of DC-DC converters 10 is less than the threshold (S203, No), the process proceeds to S205.

### S204

The diagnosis device 40 determines that an abnormality has occurred in the control of the ideal diode 30. Specifically, the diagnosis device 40 indicates a voltage value (corresponding to the voltage value of the battery 20) in which the output voltage of DC-DC converter 10 is equal to or higher than a threshold value even though the DC-DC converter 10 is stopped. Therefore, the diagnosis device 40 determines that the ideal diode 30 has a condition of ON fixation (the ideal diode 30 operates). When the diagnosis device 40 determines that an error has occurred in the control of the ideal diode 30, the diagnosis control of the ideal diode 30 at the time of IG-OFF ends.

### S205

The diagnosis device 40 determines that the control of the ideal diode 30 is normal. Specifically, since the output voltage of DC-DC converter 10 is less than the threshold while the DC-DC converter 10 is stopped, the diagnosis device 40 determines that the ideal diode 30 has no condition of ON fixation (the ideal diode 30 is not operating). When the diagnosis device 40 determines that the control of the ideal diode 30 is normal, the diagnosis control of the ideal diode 30 at the time of IG-OFF is ended.

FIG. 3 is a flow chart for explaining a process sequence of diagnostic control of the ideal-diode 30 executed by the diagnosis device 40 at the time of IG-ON. The diagnostic control of the ideal diode 30 illustrated in FIG. 3 is started when the ignition of the vehicle is turned to the on-state (IG-ON). The ignition condition of the vehicle can be determined by means of an IG signal.

### S301

The diagnosis device 40 determines whether or not the diagnosis control (FIG. 2) of the ideal diode 30 executed at the time of IG-OFF is “normal”. This determination is made to prevent false positives from occurring if they are IG-ON immediately after IG-OFF. The error diagnosis is caused by the fact that the output-voltage of DC-DC converters 10 whose operation is stopped does not sufficiently decrease at the time of diagnosis.

If the diagnosis device 40 determines that the diagnosis of the ideal-diode 30 at the time of IG-OFF is normal (S301, Yes), the process proceeds to S302. On the other hand, if the diagnosis device 40 determines that the diagnosis of the ideal-diode 30 at the time of IG-OFF is abnormal (S301, No), the process proceeds to S303.

### S302

The diagnosis device 40 determines whether or not a predetermined period of time has elapsed since the ignition of the vehicle is turned to the off-state (IG-OFF). This determination is made in order to wait for the output voltage appearing at the output of DC-DC converters 10 at the time of operation to drop sufficiently after stopping until the diagnosis can be performed. Therefore, the predetermined time is appropriately set based on, for example, the time required for discharging the charges of the capacitance connected to the output-side of DC-DC converters 10. That is, until the predetermined time elapses, the diagnosis result that the latest normal state is held without performing a new determination. When the predetermined duration has elapsed after the vehicle's ignition has been turned to the off-state (IG-OFF), the process proceeds to S303.

### S303

The diagnosis device 40 determines whether or not DC-DC converters 10 (DDC) are stopped. This determination is made on the basis of the operational status of DC-DC converter 10 because the correct diagnosis cannot be made if IG-ON causes the operation of DC-DC converter 10.

When the diagnosis device 40 determines that DC-DC converters 10 are stopped (S303, Yes), the process proceeds to S304. On the other hand, when the diagnosis device 40 determines that DC-DC converters 10 have already been operated (S303, No), the diagnostic control of the ideal diode 30 ends without performing the diagnosis at this timing.

### S304

The diagnosis device 40 acquires the output-voltage of DC-DC converter 10 (DDC). The output voltage can be obtained by monitoring the output terminal of DC-DC converter 10 using, for example, a voltage sensor. When the diagnosis device 40 acquires DC-DC converters 10 (DDC), the process proceeds to S305.

### S305

The diagnosis device 40 determines whether or not the output-voltage of DC-DC converters 10 is greater than or equal to a predetermined threshold. This determination is made in order to confirm that the anode side and the cathode side of the ideal diode 30 are conductive and that the power supply voltage necessary for the operation is supplied to the ideal diode 30. This threshold value is as described above.

When the diagnosis device 40 determines that the output voltage of DC-DC converters 10 is equal to or higher than the threshold (S305, Yes), the process proceeds to S306. On the other hand, if the diagnosis device 40 determines that the output voltage of DC-DC converters 10 is less than the threshold (S305, No), the process proceeds to S307.

### S306

The diagnosis device 40 determines that an abnormality has occurred in the control of the ideal diode 30. Specifically, the diagnosis device 40 indicates a voltage value (corresponding to the voltage value of the battery 20) in which the output voltage of DC-DC converter 10 is equal to or higher than a threshold value even though the DC-DC converter 10 is stopped. Therefore, the diagnosis device 40 determines that the ideal diode 30 has a condition of ON fixation (the ideal diode 30 operates). When the diagnosis device 40 determines that an error has occurred in the control of the ideal diode 30, the diagnosis control of the ideal diode 30 at the time of IG-ON ends.

### S307

The diagnosis device 40 determines that the control of the ideal diode 30 is normal. Specifically, since the output voltage of DC-DC converter 10 is less than the threshold while the DC-DC converter 10 is stopped, the diagnosis device 40 determines that the ideal diode 30 has no condition of ON fixation (the ideal diode 30 is not operating). When the diagnosis device 40 determines that the control of the ideal diode 30 is normal, the diagnosis control of the ideal diode 30 at the time of IG-ON is ended.

### Effects

According to the above-described embodiment, the power supply of the ideal diode 30 inserted between DC-DC converter 10 and the battery 20 is supplied from the output-side of DC-DC converter 10. With this configuration, the diagnosis device 40 monitors the output-voltage when DC-DC converters 10 are stopped. As a result, the diagnosis device 40 can detect a condition of ON fixation (a failure of the ideal diode controller IC 32, a failure of the ideal diode IC 33, a loss of the backflow preventing function, and the like) in which the ideal diode 30 continues to conduct conduction between the anode side and the cathode side.

In addition, in the diagnosis device 40 according to the present embodiment, when the condition of ON fixation of the ideal diode 30 is detected, a notification is issued via a display device, an audio device (not shown), or the like, indicating that an abnormality has occurred, so that the user of the vehicle or the like can be alerted.

In the above embodiment, the ideal diode controller IC 32 and the power supply (Vcc) of the ideal diode IC 33 are connected to the output-side of DC-DC converter 10, but they may be connected to the battery 20. Even when the ideal diode 30 is constantly operated with the electric power of the battery 20, the above-described diagnostic control of the ideal diode 30 can be performed to determine an abnormal ON fixation.

An embodiment of the present disclosure has been described above. However, the present disclosure can be regarded not only as a diagnosis device, but also as a method executed by the diagnosis device, a program of the method, a computer-readable non-transitory storage medium storing the program, a vehicle including a diagnosis device, and the like.

The diagnosis device of the present disclosure can be used in a case where a diagnosis is performed with respect to control of an ideal diode.

What is claimed is:

1. A diagnosis device that detects an abnormality of an ideal diode in an electric circuit including a direct-current (DC)-DC converter, a battery, and the ideal diode, to an anode side of which an output of the DC-DC converter is connected and to a cathode side of which the battery is connected, the diagnosis device comprising:
an acquisition unit that acquires an output voltage of the DC-DC converter with operation of the DC-DC converter stopped, the ideal diode being powered by the output of the DC-DC converter; and
a determination unit that determines that the ideal diode is abnormal when the output voltage is equal to or more than a predetermined threshold value.

2. The diagnosis device according to claim 1, wherein:
the electric circuit is mounted on a vehicle; and
the acquisition unit acquires the output voltage after ignition of the vehicle is turned off and the operation of DC-DC converter is stopped.

3. The diagnosis device according to claim 1, wherein:
the electric circuit is mounted on a vehicle; and
the acquisition unit acquires the output voltage after ignition of the vehicle is turned on and before the DC-DC converter operates.

4. The diagnosis device according to claim 2, wherein when it is determined that the ideal diode is normal when the ignition of the vehicle is turned off, the determination unit does not make a new determination for a predetermined time after determining that the ideal diode is normal.

5. The diagnosis device according to claim 3, wherein when it is determined that the ideal diode is normal when the ignition of the vehicle is turned off, the determination unit does not make a new determination for a predetermined time after determining that the ideal diode is normal.
